(19) United States
(12) Patent Application Publication
(10) Pub. No.: US 2003/0072393 A1
(43) Pub. Date: Apr. 17, 2003

(54) Quadrature transceiver substantially free of adverse circuitry mismatch effects

(76) Inventor: Jian Gu, San Diego, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/114,816

(22) Filed: Apr. 2, 2002

Related U.S. Application Data
(63) Continuation-in-part of application No. 09/922,019, filed on Aug. 2, 2001.
(60) Provisional application No. 60/311,862, filed on Aug. 13, 2001.

(51) Int. Cl. H03K 9/06

(52) U.S. Cl. 375/322

(57) ABSTRACT

A signal-balancing system and technique. The technique includes analyzing imbalance conditions of an I-Q network, deriving a set of I-Q imbalance coefficients from the analyzed imbalance conditions, and decomposing time domain samples of an input signal into frequency components. The technique also includes removing the effects of I-Q imbalance in the frequency components of the input signal by using the set of I-Q imbalance coefficients. The technique further includes converting the resulting imbalance-removed frequency components of the input signal back into time domain samples.

### CROSS REFERENCE TO RELATED APPLICATIONS

This application claims benefit of the priority of U.S. Provisional Application No. 60/311,862, filed Aug. 13, 2001, and entitled “Universal Low-IF Receiver”. This application is also a continuation-in-part of co-pending U.S. patent application Ser. No. 09/922,019, filed Aug. 2, 2001 and entitled “Method and Apparatus to Remove Effects of I-Q Imbalances of Quadrature Modulators and Demodulators in a Multi-carrier System” by the inventor of the present invention and commonly assigned to the assignee of the present invention.

### BACKGROUND

The invention relates to a quadrature transceiver. More particularly, the invention relates to balancing signals in such a quadrature transceiver.

A super-heterodyne transceiver design has traditionally been used in communication terminals. However, expanding use of wireless communication terminals is increasing the need for lower cost transceivers. Although the super-heterodyne transceiver design provides for a good quality reception, it tends to be costly and complicated.

Consequently, less costly and complex terminals have recently been introduced. Furthermore, these communication terminals may be expected to cover multiple bands and/or standards to handle many standards in different radio frequency (RF) bands. The recently introduced designs include a direct conversion (i.e. zero-IF) radio and a low-intermediate-frequency (low-IF) radio, which apply radio frequency (RF) image-reject mixing. RF image-reject mixers avoid the need for image-reject filters at the input and enable conversion of radio frequencies at a substantially reduced cost. However, a disadvantage of RF image-reject mixing designs is signal imbalances that are generated by the signal splitter unit that is coupled to the local oscillator employed for demodulation. For example, in a quadrature demodulator, the signal imbalance may be caused by a mismatch between in-phase and quadrature-phase components. Thus, it is important to have the in-phase and the quadrature-phase components of the RF local oscillator in quadrature and have substantially similar amplitudes. Any phase or amplitude imbalances may directly decrease the image-reject capabilities of the receiver. Accordingly, when these devices are employed in an integrated circuit (IC) arrangement, a desired tolerance may result in a worse than acceptable image rejection.

### SUMMARY

In one aspect, a signal-balancing method is disclosed. The method includes analyzing imbalance conditions of an I-Q network, deriving a set of I-Q imbalance coefficients from the analyzed imbalance conditions, and decomposing time domain samples of an input signal into frequency components. The method also includes removing the effects of I-Q imbalance in the frequency components of the input signal by using the set of I-Q imbalance coefficients. The method further includes converting the resulting imbalance-removed frequency components of the input signal back into time domain samples.

In another aspect, a quadrature receiver system substantially free of adverse effects of analog circuitry mismatch and component disparity is disclosed. The system is configured for a direct conversion or low-IF architecture with programmable IF frequency. The quadrature receiver system includes a quadrature demodulator and a digital I-Q balancing unit. The quadrature demodulator converts radio signal to a quadrature (I-Q formatted) signal located at a lower frequency in the same order as the radio signal bandwidth. The digital I-Q balancing unit removes the adverse effects of I-Q imbalance by converting a set of time-domain samples into a frequency domain representation by FFT. I-Q balancing technique is applied to the frequency components to remove the I-Q imbalance effects. The resulting frequency components are then converted back into a set of time-domain samples that is substantially free of I-Q imbalance. Any I-Q imbalance may be modeled as an I-Q operation (ideal or non-ideal, filtering, etc.), and in turn, as an I-Q network. Furthermore, any linear I-Q network may be decomposed into frequency components. Hence, imbalance conditions of the I-Q network may be defined by a set of N+1 imbalance matrices, if N is large enough.

### BRIEF DESCRIPTION OF THE DRAWINGS

FIG. 1A is a block diagram illustrating a typical conventional radio system.

FIG. 1B illustrates a phase mismatch between I and Q channels.

FIG. 2 is a block diagram of a quadrature receiver implemented as a low-IF receiver in which one embodiment of the invention may be practiced.

FIG. 3 is a detailed block diagram of the analog quadrature demodulator according to one embodiment of the invention.

FIGS. 4A through 4C show the magnitude of the related complex spectra in a down-conversion process.

Figures. 5A through 5C show the magnitude of the related complex spectra in a complex filtering process.

FIG. 6 is a block diagram of a digital I-Q balancing unit in accordance with one embodiment of the invention.

FIG. 7A illustrates an I-Q cross-talk network according to an embodiment of the invention.

FIG. 7B illustrates an alternative representation of the cross-talk network as three basic cascaded unbalanced networks.

FIG. 8 illustrates an example cascaded network in accordance with an embodiment of the invention.

FIG. 9 illustrates an example I-Q feed-forward network according to an embodiment of the invention.

FIG. 10 illustrates an example I-Q feedback network according to an embodiment of the invention.

FIG. 11 is a detailed basic block diagram illustrating an example of a feed-forward balancing block according to one embodiment of the invention.

FIG. 12 is a detailed basic block diagram illustrating an example of a feed-forward balancing block according to an alternative embodiment of the invention.

FIG. 13 shows an embodiment of a guarding time implemented for LM samples.

FIG. 14 is a block diagram of an (unbalanced) I-Q network.

### DETAILED DESCRIPTION

In recognition of the above-stated challenges associated with conventional signal balancing techniques in quadrature transceivers, embodiments for enhanced signal balancing techniques are described. Specifically, the techniques enable a quadrature transceiver design that is substantially free of the adverse effects of analog circuitry mismatch and component disparity. Furthermore, the system is configured for a direct conversion or low-IF architecture with programmable IF frequency. Consequently, for purposes of illustration and not for purposes of limitation, the exemplary embodiments of the invention are described in a manner consistent with such use, though clearly the invention is not so limited.

Introduction

The quadrature receiver system includes a quadrature demodulator and a digital I-Q balancing unit. The quadrature demodulator converts a radio frequency (RF) signal to a quadrature (I-Q formatted) signal located at a lower frequency but in the same order as the RF signal bandwidth. The digital I-Q balancing unit removes the adverse effects of I-Q imbalance by converting a set of time-domain samples into a frequency domain representation by fast Fourier transform (FFT). I-Q balancing technique is applied to the frequency components to remove the I-Q imbalance effects. The resulting frequency components are then converted back into a set of time-domain samples that is substantially free of I-Q imbalance.

Any I-Q imbalance may be modeled as an I-Q operation (ideal or non-ideal, filtering, etc.), and in turn, as an I-Q network. Furthermore, any linear I-Q network may be decomposed into frequency components. Hence, imbalance conditions of the I-Q network may be defined by a set of N+1 imbalance matrices, if N is large enough.

As stated above, transceivers, such as a low-intermediate-frequency (low-IF) radio or a direct conversion (i.e. zero-IF) radio, provide alternatives to the costly and complex super-heterodyne transceivers. The direct conversion scheme converts the RF signal directly into I-Q low-pass equivalent signal (i.e. baseband signal) without any intermediate-frequency (IF) stages as required by a super-heterodyne scheme. By using direct conversion scheme, the radio/analog front end is substantially simplified and many off-chip components such as Surface-Acoustic-Wave (SAW) filters may be eliminated. This enables higher level of integration for the radio/analog front end than the super-heterodyne scheme. Furthermore, this leads to lower power consumption, smaller size, and higher reliability implementation solutions.

The low-IF scheme converts the wanted radio frequency (RF) signal into a complex (I-Q valued) signal around a low-IF carrier, which is in the order of the wanted signal bandwidth. However, after the down-conversion, some adjacent channel signal appears as interference falling into the image or mirror band of the wanted signal. The channel signal in the mirror band may even be substantially stronger than the wanted signal. Thus, complex filtering involving in-phase and quadrature-phase components of the resulting low-IF signal may be needed to suppress the adjacent channel signal in the mirror band. Since IF is now in the order of the signal bandwidth, filters may be designed to reject other interferences in almost all frequency bands other than the mirror band of the wanted signal. Hence, the filters may be designed by using analog circuits in frequencies close to the baseband frequency. Therefore, SAW filters and other higher frequency stages may be eliminated to achieve higher level of integration for the radio/analog front end.

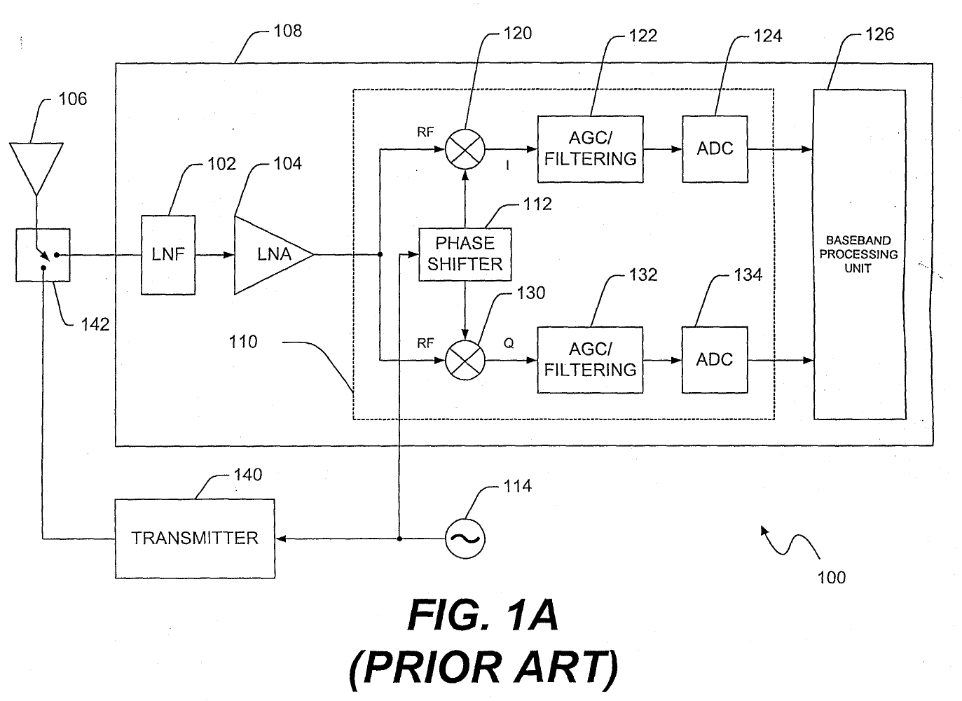

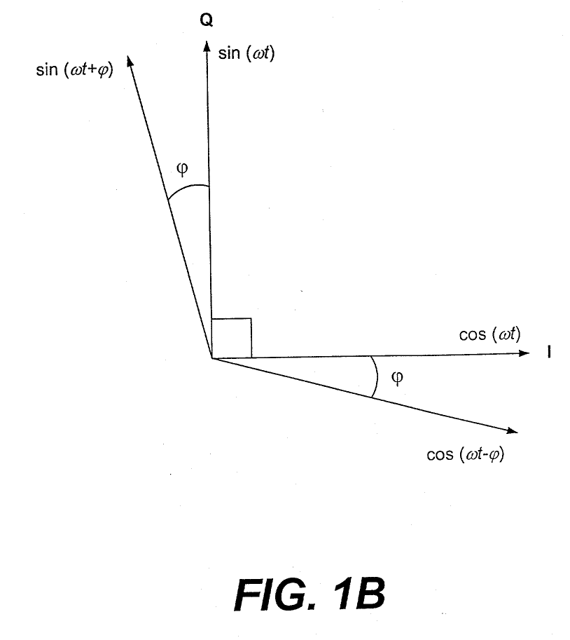

FIG. 1A is a block diagram illustrating a typical conventional radio system 100. The system 100 includes an antenna 106, a receive/transmit switch 142, a receiver 108, a transmitter 140, and a local oscillator 114.

Antenna 106 receives and transmits radio frequency (RF) signal. The received and transmitted signals may be single carrier signals or multi-carrier signals having a number of sub-carriers. In case of multi-carrier signals, each signal is a composite signal including sub-carrier signals at a number of sub-carrier frequencies. The sub-carriers are separated by a fixed frequency separation.

The receive/transmit switch 142 connects the antenna 106 to the receiver 108 or the transmitter 140 depending on whether the system 100 is in the receive mode or transmit mode, respectively. When the system 100 is configured as either a receiver or a transmitter, the receive/transmit switch 142 is not needed. The local oscillator 114 generates oscillating signal at an appropriate frequency to down convert the received signal to baseband for the receiver 108, or to up convert the baseband signal to appropriate transmission frequency for the transmitter 140.

Received RF signals are then filtered via low-noise filter (LNF) 102, and fed to an analog RF mixing demodulator 110 via low-noise amplifier (LNA) 104. The mixing demodulator 110 functions as an intermediate frequency (IF) converter of receiver 108. Furthermore, the demodulator 110 is configured as a quadrature demodulator comprising an in-phase (I) and quadrature-phase (Q) branches. The local oscillator 114 provides a sinusoidal signal to a signal splitter/phase shifter 112. The output ports of signal splitter 112 provide an in-phase reference signal (I) and a quadrature reference signal (Q) to each of the mixers 120, 130, respectively. This enables demodulation and shifting of the frequency range of the received signal from RF, such as 900 MHz, to an IF range such as 100 KHz. Each branch also includes automatic gain control and filtering units 122, 132 and analog-to-digital converters (ADC) 124, 134 to provide digital signals to an IF mixing and baseband-processing unit 126, which is designed to shift the frequency range of signals provided by RF mixing demodulator 110 to a baseband region.

As mentioned above, a significant challenge, especially for high-density modulation schemes for a system with a quadrature demodulator, such as receiver 100, is the need for a relatively accurate splitter unit in order for the local oscillator to achieve the desired image rejection. Hence, to achieve the desired image rejection, it is desirable to configure the in-phase and the quadrature phase components of the RF local oscillator 114 in such a receiver to be substantially in quadrature and to have substantially similar amplitudes. Any phase or amplitude imbalances may directly decrease the image-reject capabilities of the receiver.

I-Q imbalance caused by the mismatch between I channel and Q channel of the quadrature demodulator may include gain and group delay difference between the channels at any given frequency within the low-pass signal bandwidth. Moreover, for receivers with direct conversion or low-IF architecture, there are many amplification and filtering stages, before analog-to-digital converters (ADC) in both I and Q channels, to meet sensitivity and interference performance. Hence, the I-Q imbalance in these receivers may become more difficult to handle than other radio architecture such as super-heterodyne.

Further, the I-Q imbalance produces adverse effects on the Bit Error Rate (BER) of the receiver. Moreover, the effects may become even more adverse when a highly dense constellation modulation scheme such as 64-quadrature amplitude modulation (64-QAM) is used.

In some cases, the mismatch between I and Q channels may occur when the reference signals, cos(ωt−φ) and −sin (ωt+φ), for the I and Q mixers are not orthogonal (i.e., the phase difference is not 90 degrees if φ≢0 as shown in FIG. 1B). This may cause “cross-talk” between the in-phase component and the quadrature component.

For direct conversion receivers, there is also a DC-offset of I and Q channels. DC offset is mainly due to circuitry disparity and self-mixing products between local oscillator (LO) and received RF signals that causes the LO signal to leak through the front end to the input of the quadrature mixers and mix with the LO signal. For low-IF receivers, self-mixing product may be blocked out more easily without harming the wanted signal because the LO signal is different from the frequency of the received signal. However, the low-IF receivers may be more sensitive to I-Q imbalance of quadrature demodulator and any complex operations such as complex filtering. Nonetheless, since the effects of I-Q imbalance may be removed by the following I-Q balancing techniques, and the techniques may be extended to deal with any non-ideal complex operations, a low-IF solution may be a more desirable approach than a direct conversion solution. This may be true especially when a receiver has a severe DC offset problem due to self-mixing or other circuitry disparity and the desired signal has a significant component near DC.

I-Q Balanced Quadrature Demodulator

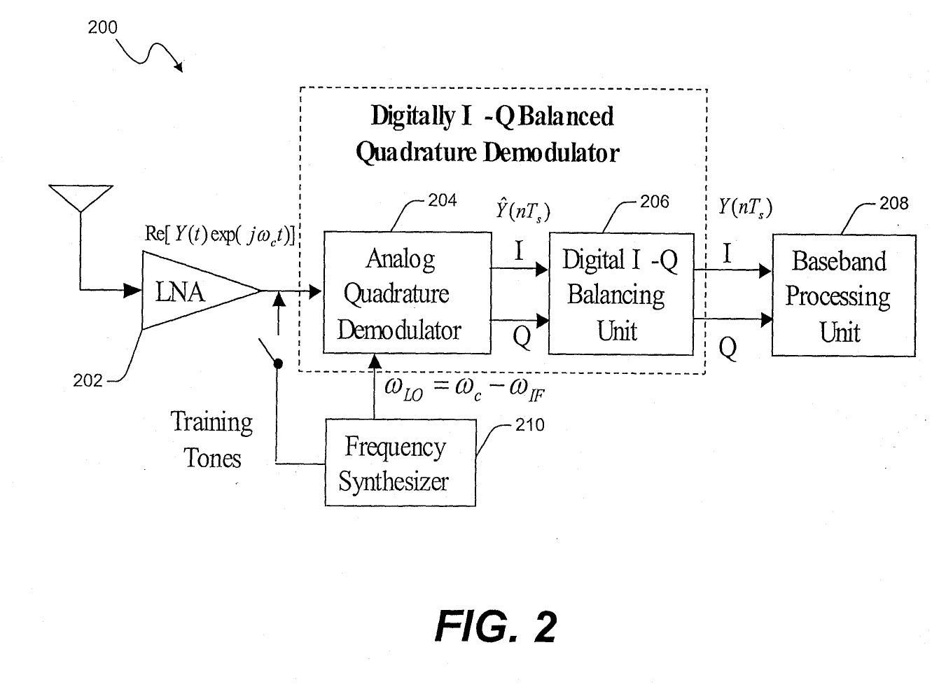

FIG. 2 is a block diagram of a quadrature receiver 200 implemented as a low-IF receiver in which one embodiment of the invention may be practiced. By setting ω_{IF}=0, the implementation becomes a direct conversion receiver. The receiver 200 may be part of a wireless communication system or any communication system with similar characteristics. The receiver 200 includes a low-noise amplifier (LNA) 202, an analog quadrature demodulator 204, a digital I-Q balancing unit 206, a baseband processing unit 208, and a frequency synthesizer 210. Not all of the elements are required for the receiver 200.

In the illustrated embodiment, the LNA stage 202 amplifies the received RF signal to an appropriate level for the analog quadrature demodulator 204. The frequency synthesizer 210, such as local oscillator, generates the desired local oscillator (LO) frequency as the reference signal to the quadrature demodulator 204. The synthesizer 210 may also generate training tones for the quadrature demodulator 204. The digital I-Q balancing unit 206 includes digital logic hardware and software for I-Q balancing function. The baseband-processing unit 208 includes any standard related baseband processing technique that depends on the characteristics of the received signal, such as modulation scheme of the signal and radio propagation environment. A combination of the analog quadrature demodulator 204 and the digital I-Q balancing unit 206 comprises a digitally I-Q balanced quadrature receiver 212.

Analog Quadrature Demodulator

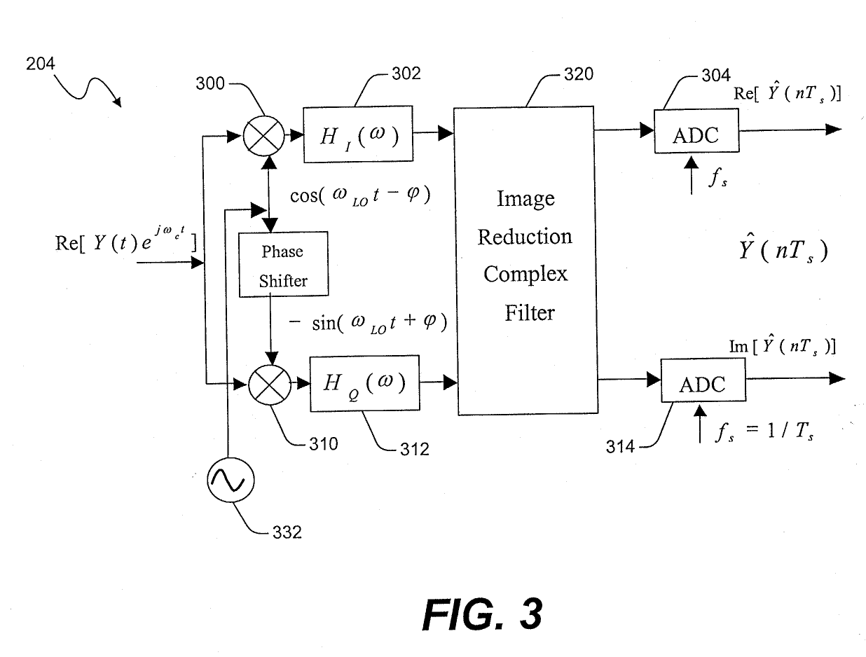

FIG. 3 is a detailed block diagram of the analog quadrature demodulator 204 according to one embodiment of the invention. The analog quadrature demodulator 204 includes down-conversion mixers 300, 310; low pass filters 302, 312; and analog-to-digital converters (ADC) 304, 314. The quadrature demodulator 204 also includes an analog image reduction complex filter 320.

In the illustrated embodiment, the received RF signal is down converted to a low-IF signal by a pair of mixers 300, 310, which splits the received signal into in-phase (I) and quadrature (Q) components and down-converts the components into a baseband signal. The baseband signal is defined in a complex-number-valued representation (i.e., I component as the real part, and Q component as the imaginary part). For example, let the base-band signal at the input of the I-Q demodulator be

Re[Y(t)·exp(jω·t)]=Re[Y(t)]cos (ωt)−Im[Y(t)]sin (ωt), (1)

where Re[.] is the real part of complex variable and Im[.] is the imaginary part of complex variable. Then at the I and Q mixer outputs, the complex representation of the signal is

Re[Y(t)]cos φ−Im[Y(t)]sin φ+j(Im[Y(t)]cos φ−Re[Y(t)]sin φ, (2)

where the terms of frequency higher than the carrier frequency are omitted. Hence, the down conversion process translates wanted real-valued signal at ω_{c} to a complex-number-valued signal at an IF frequency ω_{IF}=2πf_{IF}=ω_{c}−ω_{LO}, where ω_{LO}=ω_{c}−ω_{IF} is the local oscillator (LO) frequency. Another possible choice for the LO frequency is ω_{LO}=ω_{c}+ω_{IF}, which results in a spectrum flipping of the wanted signal that is located in the negative frequency band in terms of complex I-Q representation. For a meaningful configuration, the low IF

$$( {f}_{IF} = \frac{{ω}_{IF}}{2 π} )$$

may be as low as

$$\frac{B}{2} ,$$

but should be no higher than approximately several times B, where B is the wanted signal bandwidth. The frequency, f_{IF}, may be any number between

$$- \frac{B}{2} and \frac{B}{2} .$$

However, to avoid DC

$$\vert \frac{B}{2} \vert$$

may be a relatively small number. When f_{IF}=0, the configuration is a direct conversion receiver. A strong adjacent channel interference falling in the image band of the wanted signal may be avoided by making f_{IF} programmable to be either positive or negative, and by combining the programmed f_{IF} with adjacent interference detection techniques. This enables reduction of the requirement for the dynamic range of A/D converter.

The down-converted signals are then amplified and filtered by low-pass filters 302, 312, which remove the high frequency products from the output of the mixers 300, 310. The low-pass filters H_{I}(ω) and H_{Q}(ω) are used to reject other interferences lying outside

$$\pm ( {f}_{IF} + \frac{B}{2} ) ,$$

where B is the wanted signal (double-sided) bandwidth. In one embodiment, the low-pass filters 302, 312 are anti-aliasing filters that remove high-order harmonics of the received RF signal and local oscillator signal.

As will be discussed in detail below, the down-conversion mixers 300, 310 may also create adjacent signal inside the image frequency of the wanted signal. In this case, an analog image reduction complex filter 320 may be configured to suppress any strong adjacent signal found inside the image frequency band of the wanted signal. In some applications, adjacent channel signal level may be substantially higher than the wanted signal, for example, 20 dB higher. Accordingly, in one embodiment, a complex filter 320 may be designed to suppress negative frequency components. In a particular embodiment, the complex filter 320 may be an active poly-phase filter designed to suppress only negative frequency components. In another embodiment, passive poly-phase filters may be used to suppress only negative frequency signal. In a further embodiment, the analog complex filter 320 is configured to substantially reject negative or positive frequency components of down-converted baseband signal (e.g., in a low-IF scheme). In another further embodiment, the analog complex filter 320 is configured to provide no rejection of frequency components of down-converted baseband signal (e.g., in a direct conversion scheme).

The resultant output signal of the complex filter 320 may then be sampled and converted into digital signal samples by the A/D converters 304, 314. The sampling frequency should be high enough to represent the signal accurately. The minimum sampling frequency is fₛ=2f_{IF}+B, where B is the bandwidth of the wanted radio signal and f_{IF} is the IF frequency. Typically, B is approximately equal to the channel frequency spacing. Ideally, to preserve the same relative relationship between the original I and Q signals, mixers 300, 310, filters 302, 312, and A/D converters 304, 314 are expected to match each other relatively closely. Reference signals are also needed at the mixers 300, 310, and are expected to match in amplitude and in 90-degree phase difference. However, the output, Ŷ(nTₛ), of the A/D converters 304, 314, in general, is not I-Q balanced and, therefore, the frequency components in positive and negative frequency bands may interfere with each other. The signal mismatches in the mixers 300, 310, the filters 302, 312, the converters 304, 314, and the reference signals create I-Q imbalances.

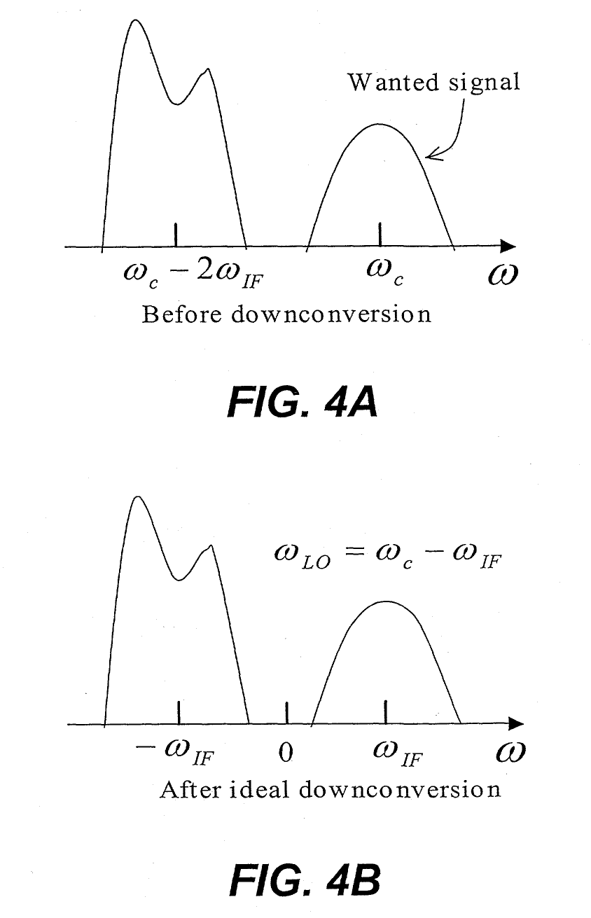

FIGS. 4A through 4C show the magnitude of the related complex spectra in the down-conversion process. As shown in the down conversion process of FIGS. 4A and 4B, the mixers 300, 310 translate wanted real-valued signal at ω_{c} to a complex-number-valued signal at an IF frequency ω_{IF}=ω_{c}−ω_{LO}, where ω_{LO} is the LO frequency. However, the down conversion process also converts an adjacent channel signal at ω_{c}−2ω_{IF} to a complex-valued signal at −ω_{IF}. For an ideal down conversion process shown in FIG. 4B, there is no interference between the first complex signal with spectrum in the negative frequency range and the second complex signal with spectrum in the positive frequency range because the spectrums are represented in terms of e^{jωt} (positive and negative frequency ranges are symmetrical relative to zero frequency). However, any imbalance between I and Q channels during the down conversion and low-pass filtering process may cause “cross-talk” between the signals in positive and negative frequency bands, as shown in FIG. 4C.

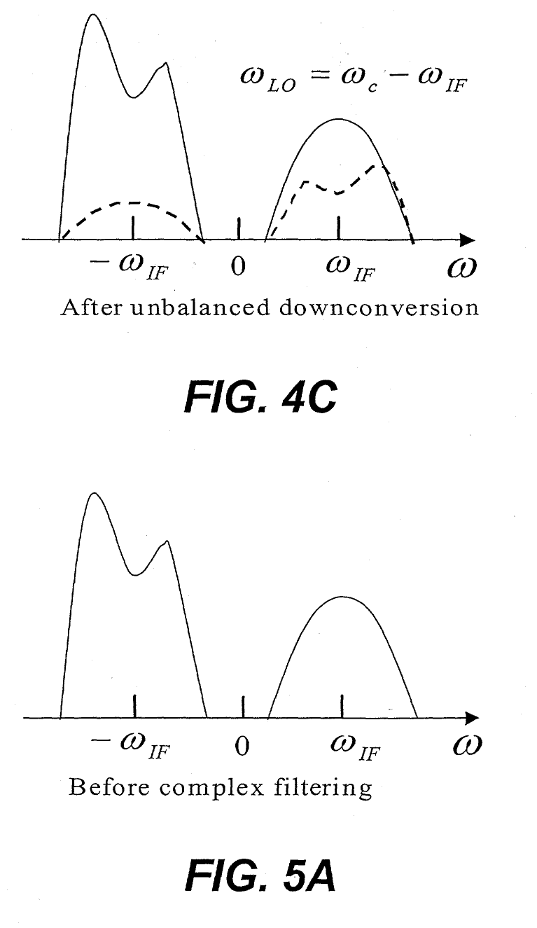

FIGS. 5A through 5C show the magnitude of the related complex spectra in the complex filtering process. For example, FIG. 5B illustrates response curves of the complex filter 320 in which a non-ideal complex filter suppresses or reduces the unwanted signal, but also introduces cross talk between positive frequency components and negative frequency components. Hence, the complex filter 320 is useful for suppressing relatively strong interference in the image band of the wanted signal. However, the complex filter 320 may also introduce additional cross talk to the wanted signal under non-ideal conditions.

In the illustrated embodiment of FIG. 5B, the center frequency of the complex filter 320 is at about ω_{IF}. However, if the center frequency of the filter 320 is tuned to zero frequency, the low-IF receiver may be configured as a direct conversion receiver.

Digital I-Q Balancing Unit

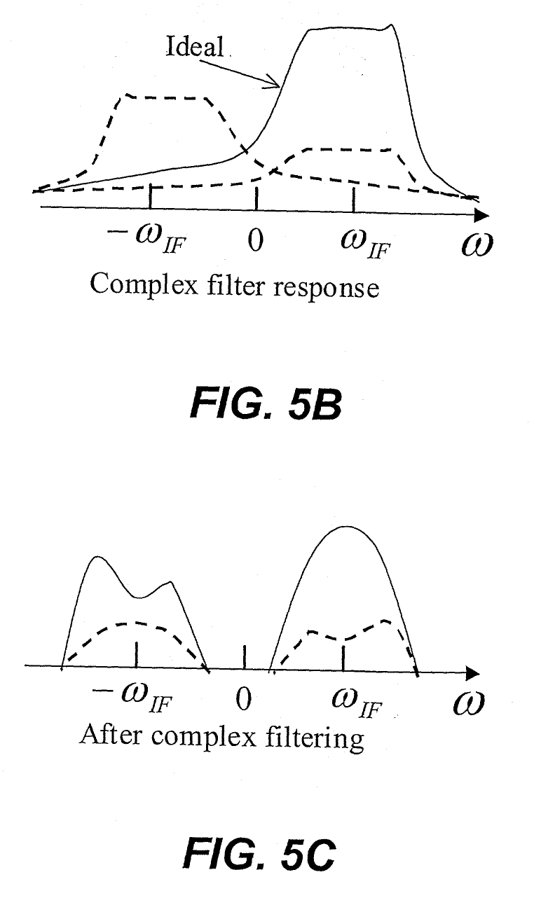

FIG. 6 is a block diagram of a digital I-Q balancing unit 206 in accordance with one embodiment of the invention. Digital I-Q balancing unit 206 includes digital logic hardware and software to perform functions of fast-Fourier transform (FFT) 602, I-Q balancing 604, optional frequency domain processing 606, and inverse fast-Fourier transform (IFFT) 608 operations. The optional frequency domain processing 606 may include frequency domain filtering, equalization, and other related processes. The I-Q balancing unit 206 also includes an input sample buffer 600 and an output sample buffer 610, to store digital samples Y(t) of the ADC output, and to store imbalance-removed samples Y(t) of the IFFT output, respectively. In one embodiment, the sample buffers are of First-In-First-Out (FIFO) type.

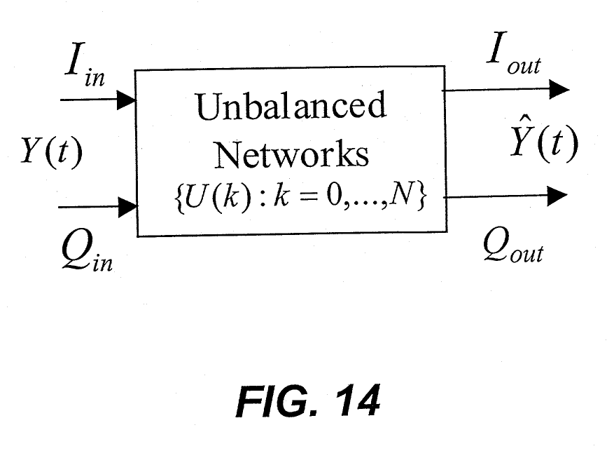

Since any signal may be represented (if bandwidth limited) or approximated (if arbitrary waveform) by Fourier series, any signal over certain duration may be decomposed into frequency components by FFT. Therefore, by converting a signal of time domain samples into frequency components over the duration, the I-Q balancing technique may be used to remove the effects of I-Q imbalance on these time domain samples. For any (unbalanced) I-Q network, such as the network shown in FIG. 14, the time domain output signal Ŷ(t) may be decomposed over certain duration, into frequency components (by FFT) in frequency domain with equal frequency spacing. Each pair of the frequency components at mutual mirror frequencies may be represented in terms of the corresponding frequency components of the input signal Y(t), as follows:

$$[ \begin{matrix}\hat{X} ( k ) \\ {\hat{X}}^{*} ( - k )\end{matrix} ] = [ \begin{matrix}{α}_{k} & {ξ}_{k} \\ {η}_{k}^{*} & {β}_{k}^{*}\end{matrix} ] [ \begin{matrix}X ( k ) \\ {X}^{*} ( - k )\end{matrix} ] , k = 0 , … , N \qquad ( 3 )$$

where

$$\hat{Y} ( t ) = {\sum }_{k = - N}^{N} \hat{X} ( k ) \cdot exp ( j2 π k {Δ}_{F} t )$$

exp(j2πkΔ_{F}t) may represent the output signal with I-Q imbalance

$$Y ( t ) = {\sum }_{k = - N}^{N} X ( k ) \cdot exp ( j2 π k {Δ}_{F} t )$$

exp (j2πkΔ_{F}t) may represent the imbalance-free input signal of the I-Q network, and Δ_{F} is the frequency spacing between the components. Asterisk indicates complex conjugate. {\hat{X}(k): |k|≦N} and {X(k): |k|≦N} are the FFT coefficients of Ŷ(t) and Y(t), respectively, over the time duration. Parameters αₖ, ξₖ, ηₖ and βₖ are referred to as imbalance coefficients, which may be derived from the imbalance conditions of the I-Q network at frequency kΔ_{F} (explained in detail in co-pending U.S. patent application Ser. No. 09/922,019). The N+1 equations in equation (3) fully define an I-Q network as shown in FIG. 14, if N is large enough.

An alternative description of an I-Q network may be obtained by decomposing input Y(t) and output Ŷ(t) signals of the network into frequency components at frequencies of ±(k−0.5)Δ_{F}, for k=1, . . . , N. In this case, equation (3) may be expressed as follows:

$$[ \begin{matrix}\hat{X} ( k ) \\ {\hat{X}}^{*} ( - k + 1 ) )\end{matrix} ] = [ \begin{matrix}{α}_{k} & {ξ}_{k} \\ {η}_{k}^{*} & {β}_{k}^{*}\end{matrix} ] [ \begin{matrix}X ( k ) \\ {X}^{*} ( - k + 1 )\end{matrix} ] , k = 1 , … , N \qquad \text{(3a)}$$

where

$$\hat{Y} ( t ) = {\sum }_{k = - N + 1}^{N} \hat{X} ( k ) \cdot exp ( j2 π ( k - 0.5 ) {Δ}_{F} t )$$

exp(j2π(k−0.5)Δ_{F}t) may represent the output signal with I-Q imbalance

$$Y ( t ) = {\sum }_{k = - N + 1}^{N} X ( k ) \cdot exp ( j2π ( k - 0.5 ) {Δ}_{F} t )$$

exp (j2π(k−0.5)Δ_{F}t) may represent the input signal of the I-Q network, and Δ_{F} is the frequency spacing between the components. Note that now the parameters αₖ, ξₖ, ηₖ and βₖ are imbalance coefficients that reflect the imbalance conditions of the I-Q network at frequency (k−0.5)Δ_{F} for k=1, . . . , N.

For any I-Q network, with an input signal

$${Y}_{i n} ( t ) = {\sum }_{k = - N}^{N} {X}_{i n} ( k ) \cdot exp ( j2π k {Δ}_{F} t )$$

exp (j2πkΔ_{F}t) and an output signal

$${Y}_{out} ( t ) = {\sum }_{k = - N}^{N} {X}_{out} ( k ) \cdot exp ( j2π k {Δ}_{F} t ) ,$$

exp(j2πkΔ_{F}t), equation (3) may be re-written as,

$$[ \begin{matrix}{X}_{out} ( k ) \\ {X}_{out}^{*} ( - k )\end{matrix} ] = [ \begin{matrix}{α}_{k} & {ξ}_{k} \\ {η}_{k}^{*} & {β}_{k}^{*}\end{matrix} ] [ \begin{matrix}{X}_{i n} ( k ) \\ {X}_{i n}^{*} ( - k )\end{matrix} ] = U ( k ) [ \begin{matrix}{X}_{i n} ( k ) \\ {X}_{i n}^{*} ( - k )\end{matrix} ] , \qquad ( 4 )$$

where U(k) is a 2-by-2 matrix called imbalance matrix.

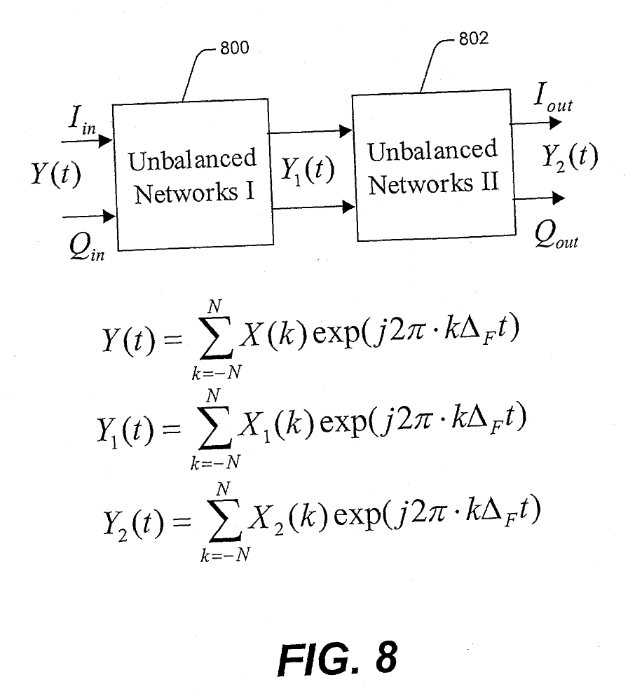

The above-derived matrix may be applied to two cascaded networks shown in FIG. 8, where the input is

$$Y ( t ) = {\sum }_{k = - N}^{N} X ( k ) \cdot exp ( j2π k {Δ}_{F} t )$$

exp(j2ρkΔ_{F}t) and outputs of the first 800 and second 802 networks are

$${Y}_{1} ( t ) = {\sum }_{k = - N}^{N} {X}_{1} ( k ) \cdot exp ( j2π k {Δ}_{F} t )$$

exp(j2πkΔ_{F}t) and

$${Y}_{2} ( t ) = {\sum }_{k = - N}^{N} {X}_{2} ( k ) \cdot exp ( j2π k {Δ}_{F} t ) ,$$

exp(j2πkΔ_{F}t), respectively. Furthermore,

$$[ \begin{matrix}{X}_{1} ( k ) \\ {X}_{1}^{*} ( - k )\end{matrix} ] = {U}_{1} ( k ) [ \begin{matrix}X ( k ) \\ {X}^{*} ( - k )\end{matrix} ] and [ \begin{matrix}{X}_{2} ( k ) \\ {X}_{2}^{*} ( - k )\end{matrix} ] = {U}_{2} ( k ) [ \begin{matrix}{X}_{1} ( k ) \\ {X}_{1}^{*} ( - k )\end{matrix} ] .$$

Therefore,

$$[ \begin{matrix}{X}_{2} ( k ) \\ {X}_{2}^{*} ( - k )\end{matrix} ] = {U}_{2} ( k ) {U}_{1} ( k ) [ \begin{matrix}X ( k ) \\ {X}^{*} ( - k )\end{matrix} ] = U ( k ) [ \begin{matrix}X ( k ) \\ {X}^{*} ( - k )\end{matrix} ] ,$$

where U₁(k) and U₂(k) are the imbalance matrices of the first 800 and second 802 networks, respectively. U(k)=U₂(k)U₁(k) is the imbalance matrix of the overall network, at the frequency ωₖ=2πkΔ_{F}.

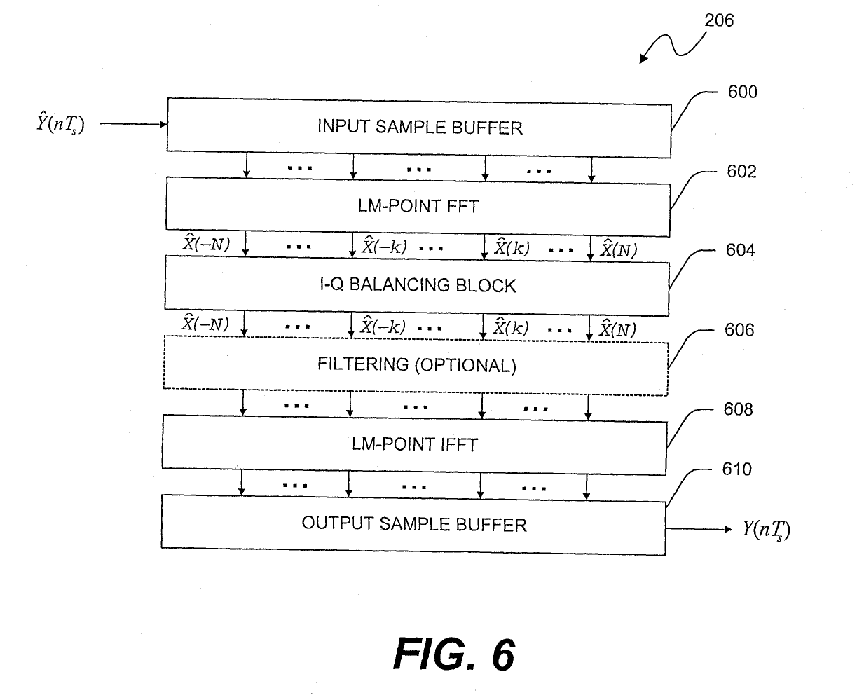

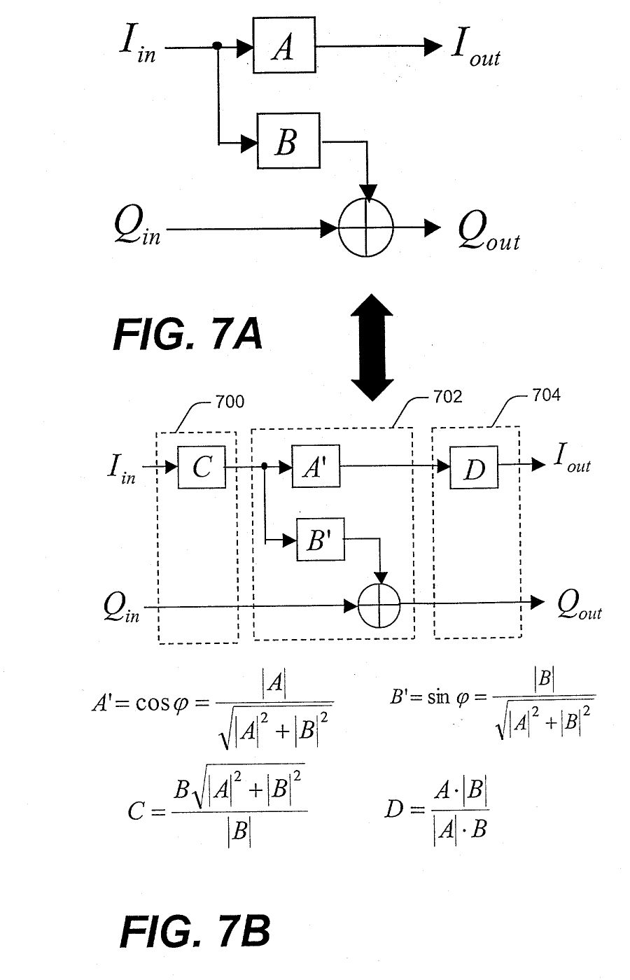

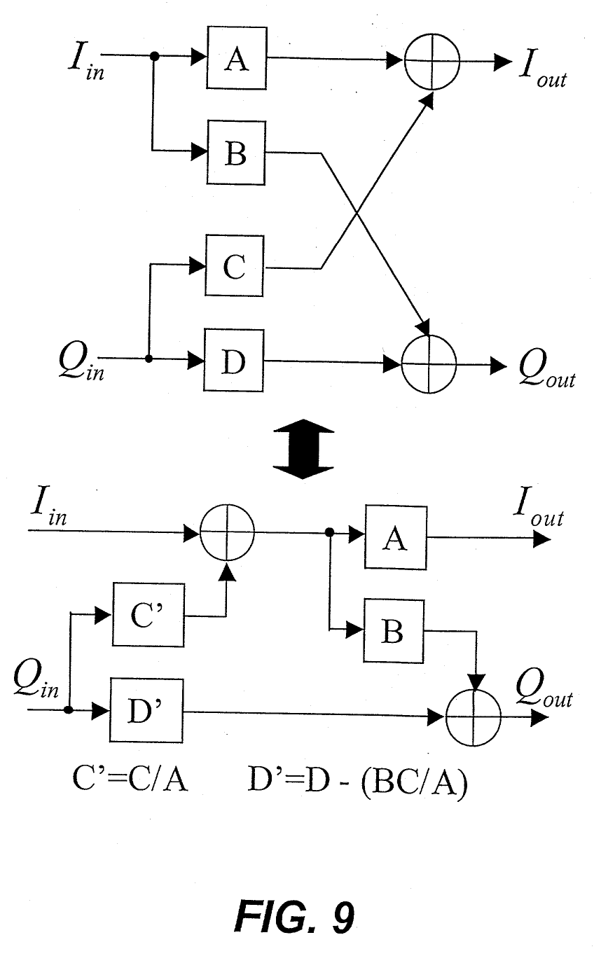

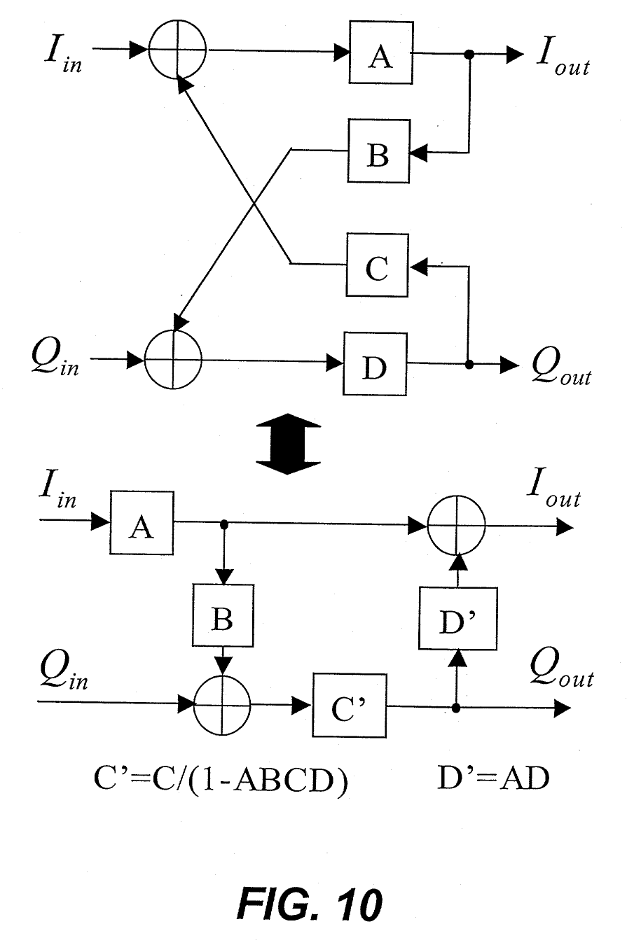

Any I-Q network may be decomposed into a number of basic unbalanced I-Q networks cascaded together. For example, FIG. 7A illustrates an I-Q cross-talk network, where A and B may be transfer functions of any realizable linear system that takes real-numbered input and generates a real-numbered output. The cross-talk network may be equivalently represented by three basic cascaded unbalanced networks (see FIG. 7B), where first 700 and third 704 networks have gain imbalance and the second network 702 has phase imbalance similar to that due to the phase offset of the I-Q mixer references. Accordingly, it can be seen that any operations related complex filtering (ideal or non-ideal) may be modeled as feed-forward (FIG. 9) or feedback (FIG. 10) networks. Parameters A, B, C, and D may be transfer functions of any realizable linear systems with gain and delay profile over a frequency band. Further, these networks may be decomposed into a number of cascaded simple I-Q cross-talk networks. Therefore, the positive and negative frequency components at the input/output of such operations may be related to each other by the “imbalance coefficients” or “imbalance matrix” described earlier.

There are many ways to obtain the imbalance coefficients, from which the inverse matrix of U(k) may be derived so that X(k) and X(−k) may be recovered from X(k) and x(−k) for a given k. One way to obtain the coefficients or the ratios of the coefficients is by sending some known training signals (such as sine wave tones) locally or remotely to the receiver (explained in detail in co-pending U.S. patent application Ser. No. 09/922,019).

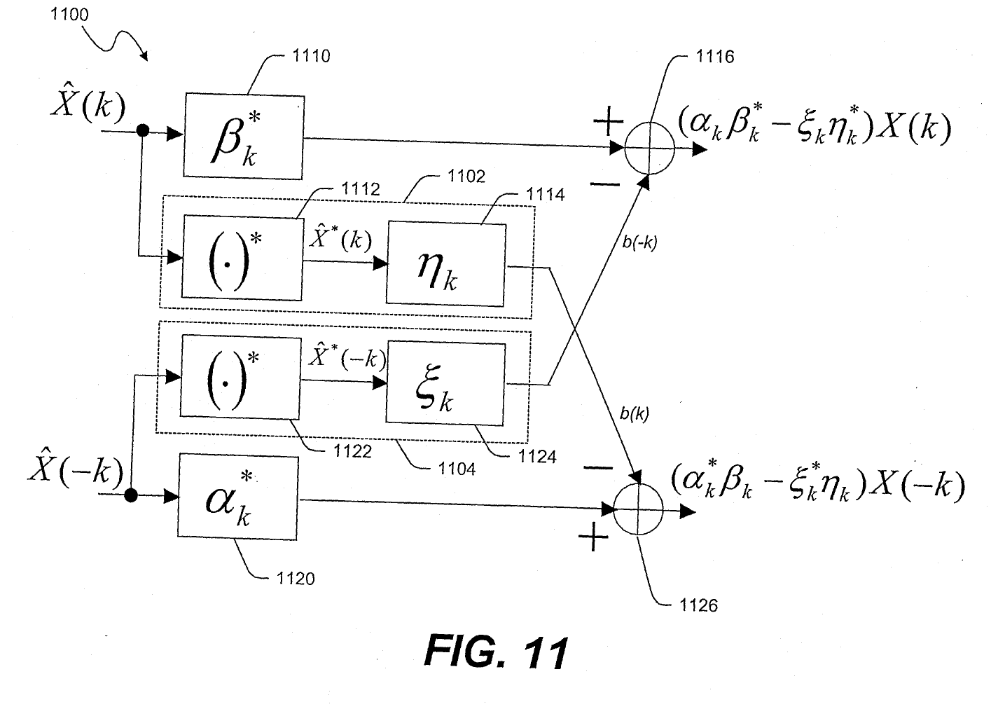

For demodulators, given the imbalance coefficients at a number of frequencies, the original signal at the input of an (unbalanced) I-Q network can be recovered as follows. FIG. 11 is a detailed basic block diagram illustrating an example of a feed-forward balancing block 1100 according to one embodiment of the invention. In one embodiment, a number (N+1) of the basic balancing blocks 1100 may be incorporated into FIG. 6 to form an I-Q balancing block 604. The block 1100 includes first and second balancer 1102 and 1104, and first and second subtractors 1116 and 1126. The input signals to the balancing block 1100 are signals \hat{X}(k) and \hat{X}(−k), which are frequency components at the k-th and −k-th frequencies indexed symmetrically about zero. The output signals of the balancing block 1100 are

Xₒᵤₜ(k)=(αₖβₖ*−ξₖηₖ*)·X(k) and Xₒᵤₜ(−k)=(αₖ*βₖ−ξₖ*ηₖ)·X(−k),

which are proportional to the frequency components of the desired signal at the I-Q network input, up to some constant complex numbers. For convenience, in FIG. 11, let the first and second input signals be \hat{X}(k) and \hat{X}(−k), the first and second balancing signals be b(k) and b(−k), and the first and second balanced signals be Xₒᵤₜ(k)=(αₖαₖ*−ξₖηₖ*)·X(k) and Xₒᵤₜ(−k)=(αₖ*βₖ−ξₖ*ηₖ)·X(−k), respectively.

The first balancer 1102 generates a first balancing signal b(k) from \hat{X}(k) of index k corresponding to the k-th sub-carrier modulator/demodulator at the sub-carrier frequency kΔ_{F}. The second subtractor 1126 subtracts the first balancing signal from the product of \hat{X}(−k) of index −k and an imbalance coefficient αₖ* 1120. The two indices of the related signals are symmetrical with respect to index zero which corresponds to a center frequency of the final composite multi-carrier signal. The second subtractor 1126 generates a second balanced signal Xₒᵤₜ(−k)=(αₖ*βₖ−ξₖ*ηₖ)·X(−k) of index −k corresponding to the component at frequency −kΔ_{F} The second balanced signal Xₒᵤₜ(−k) is a second desired signal scaled by a second complex factor.

The first balancer 1102 also includes a first conjugate converter 1112 and a first imbalance coefficient multiplier 1114. The first converter 1112 converts the first signal \hat{X}(k) into a first complex conjugate \hat{X}*(k). The first multiplier 1114 multiplies the first complex conjugate \hat{X}*(k) with an imbalance coefficient ηₖ to generate the first balancing signal b(k).

The second balancer 1104 generates a second balancing signal b(−k) from \hat{X}(−k) of index −k. The firstsubtractor 1116 subtracts the second balancing signal from the product of \hat{X}(k) of index k and an imbalance coefficient βₖ* 1110. The two indices of the related signals are symmetrical with respect to index zero which corresponds to a center frequency of the final composite multi-carrier signal. The first subtractor 1116 generates a first balanced signal Xₒᵤₜ(k)=(αₖβₖ*−ξₖηₖ*)·X(k) of index k corresponding to the component at frequency kΔ_{F}. The first balanced signal Xₒᵤₜ(k) is a first desired signal scaled by a first complex factor.

The second balancer 1104 also includes a second conjugate converter 1122 and a second imbalance coefficient multiplier 1124. The second converter 1122 converts the second signal X(−k) into a second complex conjugate X (−k). The second multiplier 1124 multiplies the second complex conjugate \hat{X}*(−k) with an imbalance coefficient ξₖ to generate the second balancing signal b(−k).

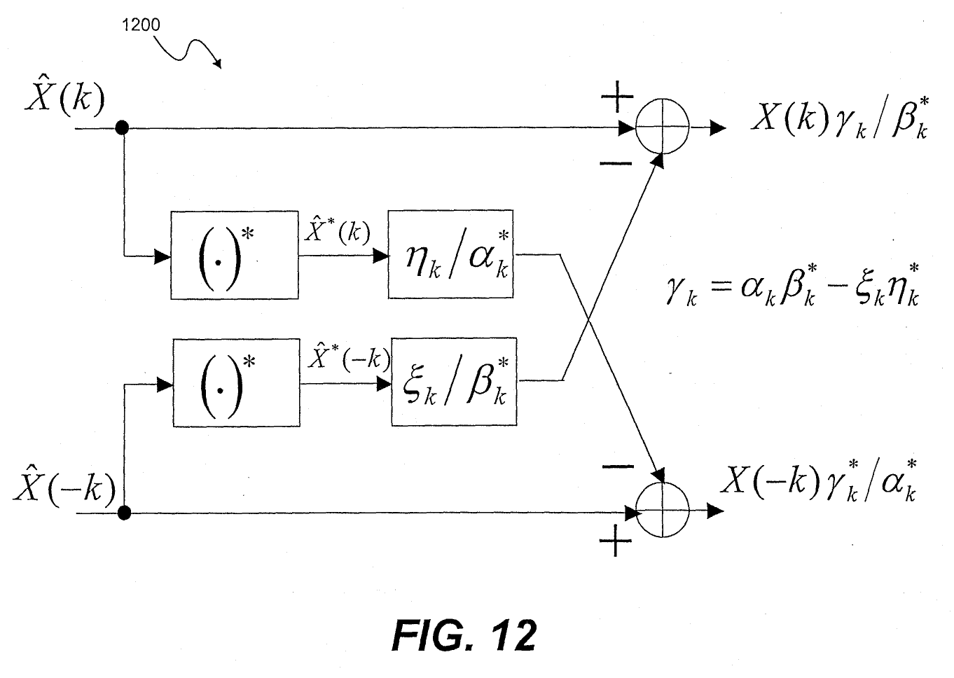

FIG. 12 shows an alternative implementation of a feed-forward basic balancing block 1200 according to one embodiment of the invention. In this implementation, imbalance coefficients αₖ* 1120 and βₖ* 1110 are removed, while the first and second imbalance coefficient multipliers 1114 and 1124 are replace with multipliers

$$\frac{{η}_{k}}{{α}_{k}^{*}} and \frac{{ξ}_{k}}{{β}_{k}^{*}} ,$$

respectively.

Referring back to FIG. 6, whenever a new set of LM samples of Ŷ(t) is stored in the sample buffer, the samples are processed by FFT 602. For a multi-carrier signal of Orthogonal Frequency Division Multiplex (OFDM) systems such as 802.11a and HiperLAN2, the parameter LM is the number of samples taken, which is larger than the number of sub-carriers (LM>2N), over one OFDM symbol. If the received signal is a single carrier signal or any other type of signals, signal samples over time duration of L symbols (e.g., L=16 symbols for M samples per symbol) may be taken. The LM-point FFT 602 may then be used to convert the LM signal samples into frequency domain samples (i.e., the signal samples are now represented by a multi-carrier signal whose sub-carriers are orthogonal to each other over the L-symbol time duration).

The I-Q balancing technique described above may be applied to the resulting frequency components of the LM time domain signal samples. LM-point IFFT 608 then converts the resulting frequency domain samples at the output of the I-Q balancing block back to time domain samples. The resulting time domain samples are substantially I-Q balanced. Additional frequency domain processing 606 such as filtering and/or equalization may be applied, if necessary, in frequency domain, after the I-Q balancing operation 604 and before the IFFT operation 608. In some embodiments, for OFDM signals, the LM-point IFFT operation may be bypassed, and the I-Q balanced frequency domain samples may be directly sent to the baseband-processing unit 208.

Another possible frequency domain processing is the adjacent channel interference detection which detects the amount of interference level outside the wanted signal band (e.g., those components at negative/positive frequencies when the wanted signal is situated on positive/negative frequency band). The detection process includes signal level calculation that sums the magnitudes (or related metrics) of the frequency components in the relevant frequencies. The result of the (interference) signal level calculation may be used to facilitate some interference avoidance mechanisms. In one of the embodiments for low-IF radio architecture in FIG. 3, the appropriate local oscillator frequency 332 and the configuration (of either rejecting signal components of negative or positive frequencies) of the complex filter 320 may be selected so that the resulting detected interference level is minimized. As a result, it may maximize the usage of the dynamic range of the Analog-to-Digital Converters (ADCs).

During the FFT and IFFT operations in FIG. 6, the resulting sub-carrier spacing is

$$\frac{{f}_{s}}{L M} ,$$

where fₛ is the sampling frequency of ADC 304, 314 in FIG. 3. Hence, the I-Q balancing technique is based on balancing coefficients that are obtained by sending training tones to the receiver. The training tone spacing may be designed to be same as the sub-carrier spacing.

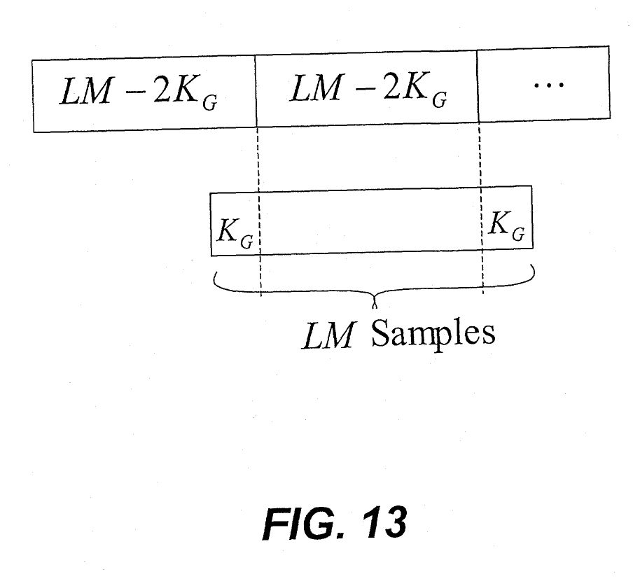

Guarding time may be required to reduce the effect of discontinuity at boundaries of different sets of LM samples since FFT assumes that the samples repeating after the received set. For multi-carrier systems such as OFDM, the guarding time is taken into consideration at signal generation by inserting some cyclic prefix. For a single carrier signal, this may be done by overlapping KG samples between consecutive sets of LM points such that the actual signal samples in the sample buffer are parsed into segments of LM-2K_{G} samples and the newly received LM-KG samples plus K_{G} previous samples of the previous set are to be processed by the FFT block 602 as shown in FIG. 13. After LM-point IFFT 608 in FIG. 6, only the middle LM-2K_{G} resulting samples are sent to the following baseband processing unit 208. The samples taken during the guarding time may be smoothed or windowed when being used for FFT processing.

The resulting signal samples. after the IFFT operation are substantially free of imbalance and crosstalk. The samples may be further processed by the following baseband processing unit 208 in FIG. 2 that may include blocks such as equalization and demodulation, depending on the modulation scheme.

For modulators/transmitters, the functions in FIG. 6 are performed in a reverse order, with the exchange of positions between the FFT and IFFT blocks. The purpose is that if Y(t) is the desired signal at the output of an (unbalanced) I-Q network, a pre-distorted signal, Ŷ(t), is applied at the input of the I-Q network so that the output of the I-Q network is Y(t). Therefore, over certain duration, given the desired signal

$$Y ( t ) = {\sum }_{k = - N}^{N} X ( k ) \cdot exp ( j 2 π k {Δ}_{F} t ) ,$$

exp(j2πkΔ_{F}t), we want to generate

$$\hat{Y} ( t ) = {\sum }_{k = - N}^{N} \hat{X} ( k ) \cdot exp ( j 2 π k {Δ}_{F} t )$$

exp(j2πkΔ_{F}t) and apply this to the (unbalanced) I-Q network so that at the output of the I-Q network is the Y(t). The input signals of a balancing block as shown in FIG. 11 or FIG. 12 are the components X(k) and X(−k) at the frequency ±kΔ_{F}. At the output of the balancing block are Xₒᵤₜ(k)=\hat{X}(k) and Xₒᵤₜ(−k)=\hat{X}(−k), which are pre-distorted frequency components at ±kΔ_{F}. All these frequency components over the duration will be applied to the IFFT operation and converted to the samples of

$$\hat{Y} ( t ) = {\sum }_{k = - N}^{N} \hat{X} ( k ) \cdot exp ( j 2 π k {Δ}_{F} t )$$

exp (j2πkΔ_{F}t) in time domain.

There has been disclosed herein embodiments for a quadrature receiver/transmitter substantially immune from I-Q imbalance caused by circuitry mismatch and component disparity. Configuration of the quadrature receiver/transmitter as a low-IF architecture is attractive because the configuration may avoid the DC offset problems, achieve high integration level and low cost implementation, and be used in multi-band/multi-standard environment. However, for any low-IF solution, there is a need to suppress the unwanted adjacent channel signal in the image band of the wanted signal, which usually requires near perfect match conditions of I-Q components. Compared with other radio architecture, low-IF solutions with prior art are more sensitive to I-Q imbalance and hence require higher accuracy analog components. Combining with I-Q balancing techniques, complex filtering, and FFT/IFFT operations, the quadrature receiver/transmitter presented above has much higher tolerance to I-Q imbalance and may be used in many digital and analog communication and broadcasting systems. For OFDM system, the receiver/transmitter has even simpler implementation. Furthermore, the quadrature receiver/transmitter may be configured as a direct conversion receiver.

While specific embodiments of the invention have been illustrated and described, such descriptions have been for purposes of illustration only and not by way of limitation. Accordingly, throughout this detailed description, for the purposes of explanation, numerous specific details were set forth in order to provide a thorough understanding of the present invention. It will be apparent, however, to one skilled in the art that the embodiments may be practiced without some of these specific details. In other instances, well-known structures and functions were not described in elaborate detail in order to avoid obscuring the subject matter of the present invention. Accordingly, the scope and spirit of the invention should be judged in terms of the claims which follow.

What is claimed is:

1. A signal-balancing method, comprising:
analyzing imbalance conditions of an I-Q network;
deriving a set of I-Q imbalance coefficients from the analyzed imbalance conditions;
decomposing time domain samples of an input signal into frequency components;
removing the effects of I-Q imbalance in the frequency components of the input signal by using the set of I-Q imbalance coefficients; and
converting the resulting imbalance-removed frequency components of the input signal back into time domain samples.

2. The method of claim 1, wherein the removing the effects of I-Q imbalance includes processing at least one signal pair, each of which includes first and second input signals corresponding to two frequency components that are symmetrical with respect to zero frequency, and are associated with at least first, second, third, and fourth imbalance coefficients.

3. The method of claim 2, wherein processing each signal pair includes generating a first balancing signal.

4. The method of claim 3, wherein the generating a first balancing signal includes converting the first input signal into a first complex conjugate.

5. The method of claim 4, wherein the generating a first balancing signal further includes multiplying the first complex conjugate with the first imbalance coefficient.

6. The method of claim 2, wherein processing each signal pair includes generating a second output signal by combining the first balancing signal with a product of the second input signal and the third imbalance coefficient.

7. The method of claim 2, wherein processing each signal pair includes generating a second balancing signal.

8. The method of claim 7, wherein the generating a second balancing signal includes converting the second input signal into a second complex conjugate.

9. The method of claim 8, wherein the generating a second balancing signal further includes multiplying the second complex conjugate with the second imbalance coefficient.

10. The method of claim 2, wherein processing each signal pair includes generating a first output signal by combining the second balancing signal with a product of the first input signal and a fourth imbalance coefficient.

11. The method of claim 1, further comprising:
storing the time domain samples of the input signal prior to the decomposing of the samples in terms of frequency components; and
storing the output samples subsequent to the converting of the frequency components into time domain samples.

12. The method of claim 1, further comprising:
providing signal level calculation by summing magnitude-related metrics of the frequency components of interest, subsequent to the removing of the I-Q imbalance.

13. The method of claim 1, further comprising:
processing the frequency components by appropriately scaling the frequency components with complex numbers, subsequent to the removing of the I-Q imbalance.

14. A quadrature receiver system, comprising:
a local oscillator and a phase splitter to generate a pair of reference signals;
a pair of down-converters to receive and convert a radio frequency (RF) signal to desired I-Q baseband signals using the reference signals;
a pair of low-pass filters to remove high-order harmonics generated during the down-conversion process;
an analog complex filter to substantially reject interference located on the image frequencies of the desired signals after down-conversion;
a pair of analog-to-digital converter (ADC) to convert the filtered analog signals into a pair of digital signals; and
a digital I-Q balancing unit to remove the adverse effect of I-Q imbalance in the pair of digital signals.

15. The system of claim 14, wherein the pair of low-pass filters are anti-aliasing filters.

16. The system of claim 14, wherein the analog complex filter is configured to substantially reject negative or positive frequency components of the down-converted baseband signals.

17. The system of claim 14., wherein the analog complex filter is configured to provide substantially no rejection of frequency components of the down-converted baseband signals.

18. An I-Q signal-balancing system, comprising:
an I-Q network imbalance condition analyzer to derive a set of I-Q imbalance coefficients;
a first buffer to receive and store time domain samples of an input signal;
a time-domain-to-frequency-domain transformer to decompose the time domain samples of the input signal into frequency components;
an I-Q balancing unit to remove the effects of I-Q imbalance in the frequency components of the input signal by using the set of I-Q imbalance coefficients; and
a frequency-domain-to-time-domain transformer converting the resulting imbalance-removed frequency components of the input signal back into time domain samples.

19. The system of claim 18, further comprising:
a second buffer to receive and store the resulting imbalance-removed time domain samples of the input signal.

20. The system of claim 18, wherein the time-domain-to-frequency-domain transformer includes an LM-point fast Fourier transform (FFT), where LM indicates signal samples taken over time duration of L symbols.

21. The system of claim 18, wherein the frequency-domain-to-time-domain transformer includes an LM-point inverse fast Fourier transform (IFFT), where LM indicates signal samples taken over time duration of L symbols.

22. The system of claim 18, wherein the I-Q balancing unit includes:
at least one pair of first and second receivers to receive a pair of first and second input signals;
a first balancer to generate a first balancing signal by processing the first input signal;
a second balancer to generate a second balancing signal by processing the second input signal;
a second combiner to generate a second output signal by combining the first balancing signal with the second input signal; and
a first combiner to generate a first output signal by combining the second balancing signal with the first input signal.

23. The system of claim 22, wherein the first balancer includes:
a complex conjugator to generate a complex conjugate of the first input signal; and
a multiplier to produce a product of the complex conjugate with a first imbalance coefficient.

24. The system of claim 22, wherein the second balancer includes:
a complex conjugator to generate a complex conjugate of the second input signal; and
a multiplier to produce a product of the complex conjugate with a second imbalance coefficient.
